(19) United States
(12) Patent Application Publication
(10) Pub. No.: US 2019/0260165 A1
(43) Pub. Date: Aug. 22, 2019

(54) CABLE TERMINATION FOR CONNECTORS

(71) Applicant: The Siemon Company, Watertown, CT (US)

(72) Inventors: Randy J. Below, Cheshire, CT (US); Jason Ellison, New Cumberland, PA (US); Bob Harisi, Waterbury, CT (US); Joseph M. Favale, SR., Watertown, CT (US)

(21) Appl. No.: 16/274,559

(22) Filed: Feb. 13, 2019

Related U.S. Application Data
(60) Provisional application No. 62/631,575, filed on Feb. 16, 2018.

(51) Int. Cl. H01R 13/6471; H01R 13/66; H01R 13/6593; H01R 12/59; H01R 9/03; H01R 13/6594; H01R 13/6474; H05K 3/34; H01R 12/72

(52) U.S. Cl. CPC H01R 13/6471; H01R 13/6658; H01R 13/6593; H01R 12/596; H01R 12/721; H01R 13/6594; H01R 13/6474; H05K 3/3405; H01R 9/03

(57) ABSTRACT

A connector for use with a cable. The cable includes a first signal conductor, a second signal conductor and a drain conductor. The connector includes a termination structure; a first signal connection point on the termination structure, the first signal conductor electrically terminated to the first signal connection point; a second signal connection point on the termination structure, the second signal conductor electrically terminated to the second signal connection point; a drain connection point on the termination structure, the drain conductor electrically terminated to the drain connection point; wherein the drain connection point is located between the first signal connection point and the second signal connection point.

### CROSS-REFERENCE TO RELATED APPLICATIONS

This application claims the benefit of U.S. provisional patent application Ser. No. 62/631,575, filed Feb. 16, 2018, the entire contents of which are incorporate herein by reference.

### TECHNICAL FIELD

The subject matter disclosed herein relates generally to cable termination, and more particularly, to cable termination for connectors, such as, small form-factor connectors.

### BACKGROUND

Conventional cable interconnection systems are found in electronic devices such as routers, servers and the like, and are used to form signal transmission lines. US patent application publication 20140206230 depicts an example cable termination using a cable assembly having four cables, each cable including a pair of signal conductors and a single drain or ground wire. In terminating the drain conductor to a circuit board, the drain conductor is repositioned to the outside of the pair of signal conductors. Positioning the drain conductor in this manner can degrade the electrical performance of the cable interconnection system.

US patent application publication 20140182885 uses a cable assembly in which each cable includes two signal conductors and two drain conductors. While the use of a cable having two drain conductors improves electrical performance, such cables are more expensive and may be harder to source when compared to cables having a single drain conductor.

### SUMMARY

According to an embodiment, a connector is provided for use with a cable including a first signal conductor, a second signal conductor and a drain conductor, the connector including a termination structure; a first signal connection point on the termination structure, the first signal conductor electrically terminated to the first signal connection point; a second signal connection point on the termination structure, the second signal conductor electrically terminated to the second signal connection point; a drain connection point on the termination structure, the drain conductor electrically terminated to the drain connection point; wherein the drain connection point is located between the first signal connection point and the second signal connection point.

According to another embodiment, a connector is provided for use with a cable including at least one signal conductor, the connector including a termination structure; a reference plane; and a dielectric material encasing a portion or all of the signal conductor extending beyond a cable jacket; wherein the conductor is positioned relative to the reference plane and the dielectric material is positioned such that the connector has a desired impedance.

According to another embodiment, a connector is provided for use with a cable including a first signal conductor, a second signal conductor and a drain conductor, the connector including a termination structure; a first signal connection point on the termination structure, the first signal conductor electrically terminated to the first signal connection point; a second signal connection point on the termination structure, the second signal conductor electrically terminated to the second signal connection point; a drain connection point on the termination structure; a further first signal connection point on the termination structure, a further first signal conductor electrically terminated to the further first signal connection point; a further second signal connection point on the termination structure, a further second signal conductor electrically terminated to the further second signal connection point; a further drain connection point on the termination structure; a dielectric material encasing a portion or all of the first signal conductor extending beyond a cable jacket, a portion or all of the second signal conductor extending beyond the cable jacket and a portion or all of the drain conductor extending beyond the cable jacket; a further dielectric material encasing a portion or all of the further first signal conductor extending beyond a cable jacket, a portion or all of the further second signal conductor extending beyond the cable jacket and a portion or all of the further drain conductor extending beyond the cable jacket; wherein the dielectric material and the further dielectric material are applied in discrete, non-contiguous sections.

The foregoing features and elements may be combined in various combinations without exclusivity, unless expressly indicated otherwise. These features and elements as well as the operation thereof will become more apparent in light of the following description and the accompanying drawings. It should be understood, however, that the following description and drawings are intended to be illustrative and explanatory in nature and non-limiting.

### BRIEF DESCRIPTION OF THE DRAWINGS

Referring now to the drawings wherein like elements are numbered alike in the FIGURES:

FIG. 1 is a perspective view of cables terminated to a connector in an example embodiment;

FIG. 2 is a perspective view of cables terminated to a connector in an example embodiment;

FIG. 3 is a perspective view of cables terminated to a connector in an example embodiment;

FIG. 4 is a perspective view of cables terminated to a connector in an example embodiment;

FIG. 5 is a perspective view of cables terminated to a connector in an example embodiment;

FIG. 6 is a side view of cables terminated to a connector in an example embodiment;

FIG. 7 illustrates electrical performance of a connector in an example embodiment.

### DETAILED DESCRIPTION

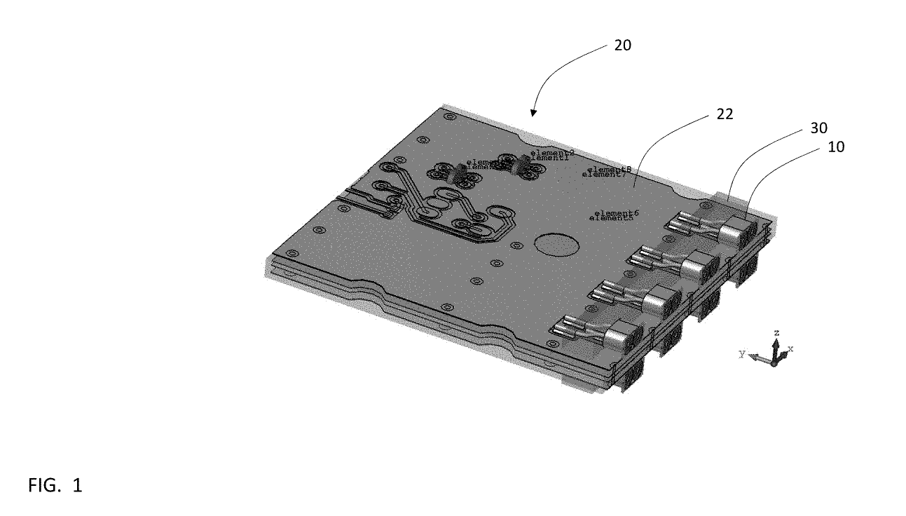

FIG. 1 is a perspective view of a cables 10 terminated to a connector 20 in an example embodiment. The cables 10 may be individual cables or part of a cable assembly (e.g., multiple cables inside a common jacket). In the embodiment of FIG. 1, the connector 20 includes termination structure in the form of a circuit board 22. The connector 20 may be a QFSP paddle card. The cable termination described herein may work with other types of connectors, such as lead frame connectors, etc. The circuit board 22 may be part of a small form-factor connector, referred to a SFP or QSFP connectors.

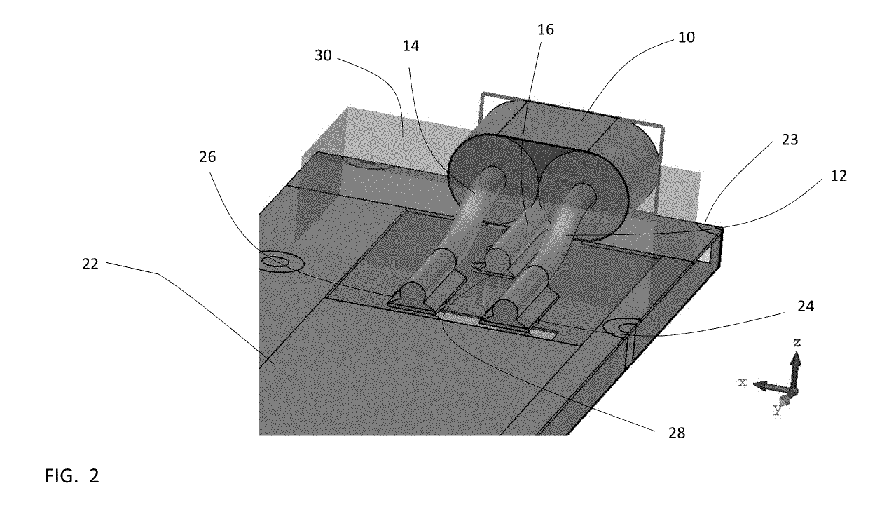

FIG. 2 is a perspective view of a cable 10 terminated to the circuit board 22 in an example embodiment. The cable 10 includes a first signal conductor 12, a second signal conductor 14 and a drain conductor 16 (also referred to as a ground wire). Cable 10 may include one or more drain conductors 16. The circuit board includes a first signal connection point 24, a second signal connection point 26 and a drain connection point 28. The first signal conductor 12, second signal conductor 14 and drain conductor 16 are electrically connected to the first signal connection point 24, the second signal connection point 26 and the drain connection point 28, respectively. The first signal connection point 24, the second signal connection point 26 and the drain connection point 28 may be solder pads on the circuit board 22. The drain connection point 28 may be part of a larger ground plane formed on the circuit board 22. It is understood that the first signal connection point 24, the second signal connection point 26 and the drain connection point 28 may be implemented using structures other than solder pads such as plated through holes, insulation displacement contacts, etc.

The arrangement and location of the first signal connection point 24, the second signal connection point 26 and the drain connection point 28 provide for a compact termination which improves electrical performance of the connector. Cable 10 is introduced to the connector at a leading edge 23 of the termination structure, which is the printed circuit board 22 in the embodiment of FIG. 2. The cable is prepared so that the jacket of the cable 10 will overlap the circuit board 22 after termination. The drain connection point 28 is positioned between the first signal connection point 24 and the second signal connection point 26. The drain connection point 28 is also closer to the cable 10 and the leading edge 23 of the circuit board 22 than the first signal connection point 24 and the second signal connection point 26. The first signal connection point 24 and the second signal connection point 26 may be equidistant from the leading edge 23. When cable 10 is prepared for termination, first signal conductor 12 and a second signal conductor 14 have a length extending beyond the jacket of cable 10 that is greater than a length of the drain conductor 16 extending beyond the jacket of cable 10. As shown in FIG. 1, the connector 20 may include a plurality of cables 10 terminated to the circuit board 22, on both a first side and a second side of the circuit board 22.

The position of the drain connection point 28 eliminates the need of prior designs to reposition the drain conductor 16 around the cable 10. This repositioning of the drain conductor 16 negatively effects electrical performance of the connector, for example, by increasing the inductive loop of the ground causing a ground-mode resonance.

Also depicted in FIG. 2 is a dielectric material 30 that encases a portion or all of the first signal conductor 12 extending beyond the cable jacket, a portion or all of the second signal conductor 14 extending beyond the cable jacket and a portion or all of the drain conductor 16 extending beyond the cable jacket. The dielectric material 30 may be applied by heating the dielectric material 30 to a melted state and then applying the molten dielectric material 30 to the circuit board 22. The dielectric material 30 may be applied using a light cured material (e.g., UV curable) applied to the circuit board 22 and then cured. The dielectric material 30 may be applied across all the cables 10 on one side of the circuit board in a single application of contiguous dielectric material 30 (see FIG. 1).

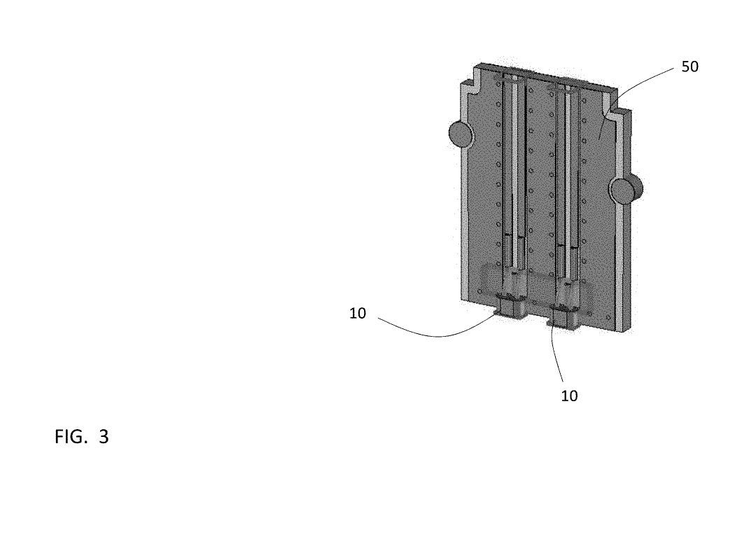

FIG. 3 is a perspective view of cables 10 terminated to a circuit board 50 in an example embodiment. Circuit board 50 is, in one example, part of an SFP paddle card. The transmission line on circuit board 50 is a co-planar grounded microstrip instead of a stripline in the case of the QSFP example of FIG. 1. Cable 10 is terminated to circuit board 50 in the same manner as shown in FIG. 2.

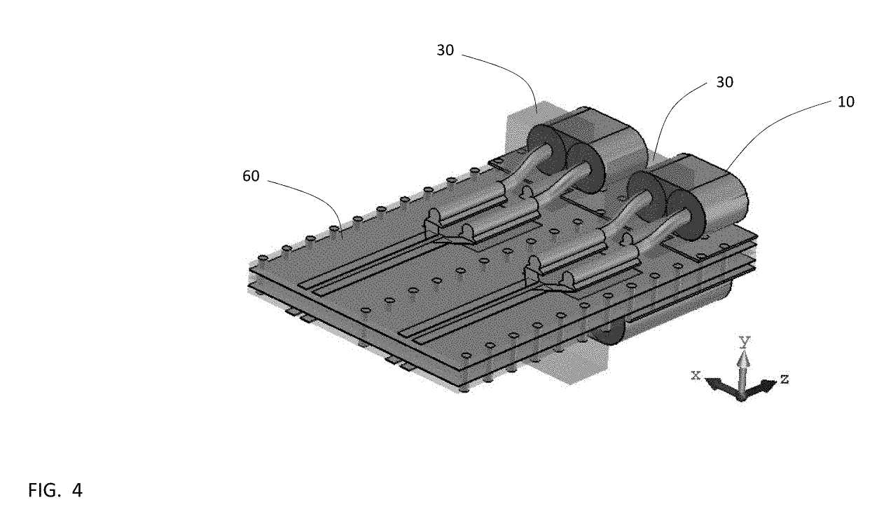

FIG. 4 is a perspective view of cables 10 terminated to a circuit board 60 in an example embodiment. Circuit board 60 includes stripline transmission lines. In the embodiment of FIG. 4, the dielectric material 30 is applied in discrete, non-contiguous sections at each cable 10. Application of the dielectric material 30 in discrete, non-contiguous sections may be used with a variety of termination structures. By controlling the gaps between the discrete, non-contiguous sections of dielectric material 30, the impedance can be controlled to meet desired levels.

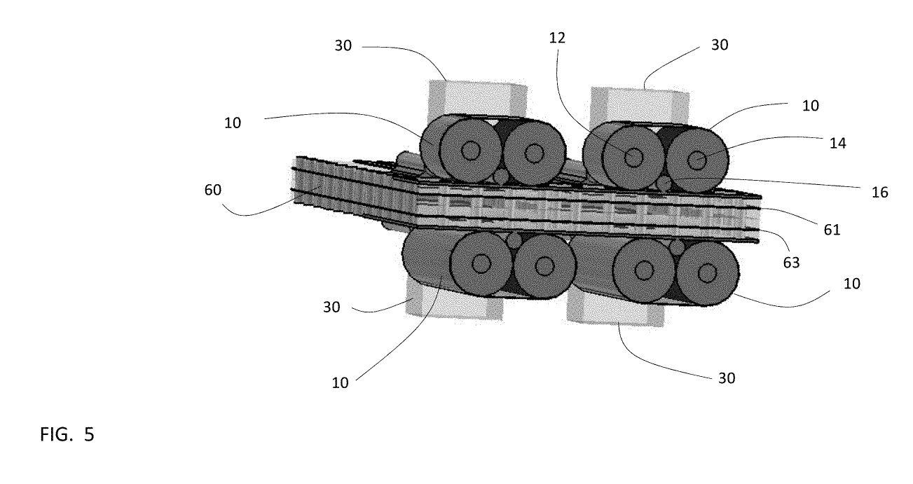

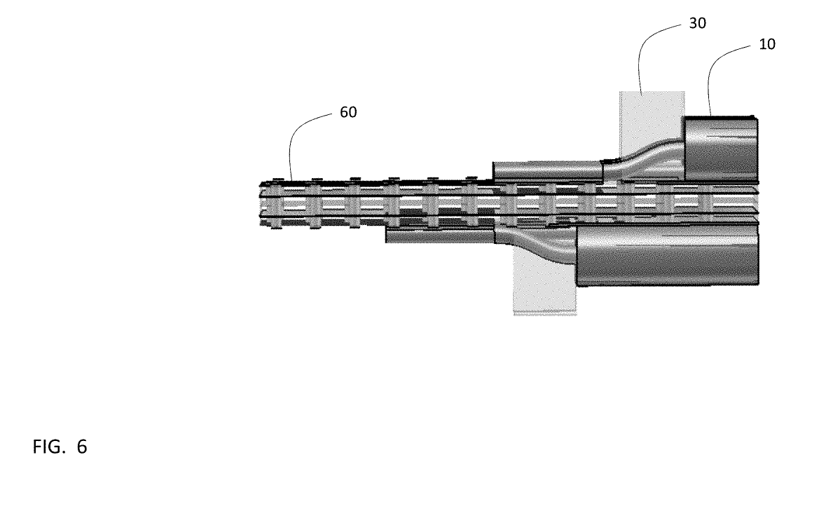

FIG. 5 is a rear, perspective, cross-sectional view of cables 10 terminated to the circuit board 60 of FIG. 4. Depicted in FIG. 5 is the arrangement of the first signal conductor 12, the second signal conductor 14 and the drain conductor 16 within cable 10. Also depicted in FIG. 5 are ground planes 61 and 63, formed as layers in the circuit board 60. Ground plane 61 may serve as a ground plane for cables 10 terminated on the first side of the circuit board 60. Ground plane 63 may serve as a ground plane for cables 10 terminated on the second side of the circuit board 60, opposite the first side. FIG. 6 is a side view of cables 10 terminated the circuit board 60 of FIG. 4.

The cable termination described herein allows for superior signal integrity (SI) performance using a center drain twinaxial cable. The location of the drain connection point results in a short, low inductance return path and thus eliminates resonating emissions. The inclusion of the dielectric material minimizes reflections. The termination structure shown and described herein is a circuit board, but embodiments may be applied to termination structures employing lead frames, IDCs and other attachment methods.

Embodiments provide a connector of controlled impedance (e.g., differential impedance) by using a dielectric material surrounding a portion or all of or more conductors of a cable. Impedance is also controlled by setting the distance between the conductor and a reference, such as a metallic plane, which may be in the form of a ground plane. The impedance can be referencing any multiconductor impedance with or without a dedicated return path or single conductor impedance with a dedicated return path. The metallic plane can be physical (such as ground planes 61 or 63) or non-physical for computational purposes in the case of a multiconductor system without a dedicated return path.

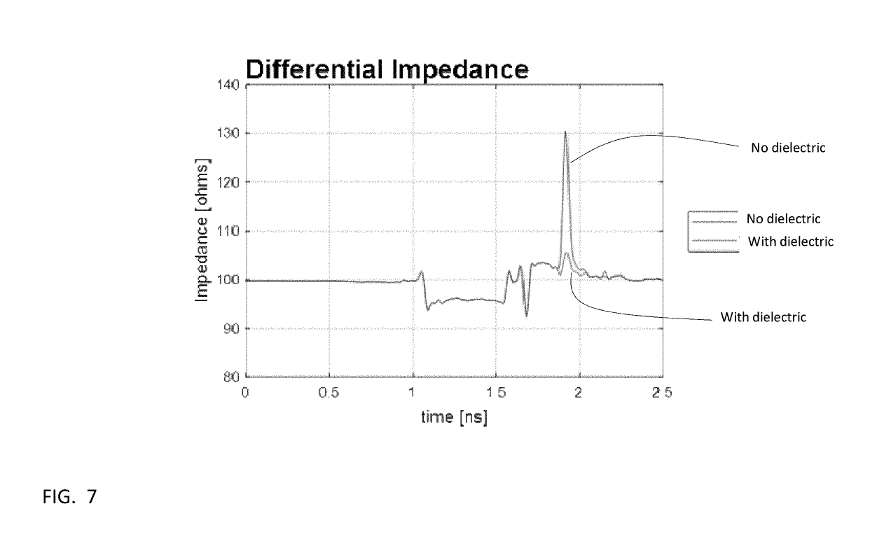

FIG. 7 illustrates improved electrical performance of a connector having the dielectric material 30. FIG. 7 illustrates impedance (e.g., differential impedance) for a connector having no dielectric 30 and a connector having a dielectric 30 installed. On the time scale, from time 0 to 1 is before the reference plane of the measurement, from time 1 to 1.5 is a test fixture, from time 1.5 to 1.7 is the mating connector and from 1.7 to 2 is the connector 20. As shown in FIG. 7, the impedance spikes at about 1.9 ns to 130 ohms for connectors lacking the dielectric material 30. By contrast, using the dielectric material 30 provides an impedance between 85 ohms and 110 ohms at the connector 20.

The terminology used herein is for the purpose of describing particular embodiments only and is not intended to be limiting of the invention. While the description of the present invention has been presented for purposes of illustration and description, it is not intended to be exhaustive or limited to the invention in the form disclosed. Many modifications, variations, alterations, substitutions, or equivalent arrangement not hereto described will be apparent to those of ordinary skill in the art without departing from the scope and spirit of the invention. Additionally, while the various embodiments of the invention have been described, it is to be understood that aspects of the invention may include only some of the described embodiments. Accordingly, the invention is not to be seen as being limited by the foregoing description.

What is claimed is:

1. A connector for use with a cable comprising a first signal conductor, a second signal conductor and a drain conductor, the connector comprising:
a termination structure;
a first signal connection point on the termination structure, the first signal conductor electrically terminated to the first signal connection point;
a second signal connection point on the termination structure, the second signal conductor electrically terminated to the second signal connection point;
a drain connection point on the termination structure, the drain conductor electrically terminated to the drain connection point;
wherein the drain connection point is located between the first signal connection point and the second signal connection point.

2. The connector of claim 1 wherein the termination structure includes a leading edge where the cable is introduced to the connector, the drain connection point positioned closer to the leading edge than the first signal connection point and the second signal connection point.

3. The connector of claim 1 further comprising a dielectric material encasing a portion or all of the first signal conductor extending beyond a cable jacket, a portion or all of the second signal conductor extending beyond the cable jacket and a portion or all of the drain conductor extending beyond the cable jacket.

4. The connector of claim 1 wherein the termination structure further comprises:
a further first signal connection point on the termination structure, a further first signal conductor electrically terminated to the further first signal connection point;
a further second signal connection point on the termination structure, a further second signal conductor electrically terminated to the further second signal connection point;
a further drain connection point on the termination structure, a further drain conductor electrically terminated to the further drain connection point;
wherein the further drain connection point is located between the further first signal connection point and the further second signal connection point.

5. The connector of claim 4 further comprising a further dielectric material encasing a portion or all of the further first signal conductor extending beyond a cable jacket, a portion or all of the further second signal conductor extending beyond the cable jacket and a portion or all of the further drain conductor extending beyond the cable jacket.

6. The connector of claim 5 wherein the dielectric material and the further dielectric material are applied in discrete, non-contiguous sections.

7. The connector of claim 5 wherein the dielectric material and the further dielectric material are applied in a single application of contiguous dielectric material.

8. The connector of claim 1 wherein the termination structure is a circuit board.

9. The connector of claim 1 wherein the first signal connection point, the second signal connection point and the drain connection point are solder pads.

10. The connector of claim 1 wherein an impedance of the connector ranges from 90 ohms to 110 ohms.

11. A connector for use with a cable having at least one signal conductor, the connector comprising:
a termination structure;
a reference plane; and
a dielectric material encasing a portion or all of the signal conductor extending beyond a cable jacket;
wherein the conductor is positioned relative to the reference plane and the dielectric material is positioned such that the connector has a desired impedance.

12. The connector of claim 11 wherein the reference plane is a ground plane.

13. A connector for use with a cable comprising a first signal conductor, a second signal conductor and a drain conductor, the connector comprising:
a termination structure;
a first signal connection point on the termination structure, the first signal conductor electrically terminated to the first signal connection point;
a second signal connection point on the termination structure, the second signal conductor electrically terminated to the second signal connection point;
a drain connection point on the termination structure;
a further first signal connection point on the termination structure, a further first signal conductor electrically terminated to the further first signal connection point;
a further second signal connection point on the termination structure, a further second signal conductor electrically terminated to the further second signal connection point;
a further drain connection point on the termination structure;
a dielectric material encasing a portion or all of the first signal conductor extending beyond a cable jacket, a portion or all of the second signal conductor extending beyond the cable jacket and a portion or all of the drain conductor extending beyond the cable jacket;
a further dielectric material encasing a portion or all of the further first signal conductor extending beyond a cable jacket, a portion or all of the further second signal conductor extending beyond the cable jacket and a portion or all of the further drain conductor extending beyond the cable jacket;
wherein the dielectric material and the further dielectric material are applied in discrete, non-contiguous sections.
